(19) United States
(12) Patent Application Publication
(10) Pub. No.: US 2017/0279078 A1
(43) Pub. Date: Sep. 28, 2017

(54) METHOD OF MANUFACTURING AN ORGANIC EL DISPLAY DEVICE

(71) Applicant: Japan Display Inc., Minato-ku (JP)

(72) Inventor: Akinori KAMIYA, Minato-ku (JP)

(73) Assignee: Japan Display Inc., Minato-ku (JP)

(21) Appl. No.: 15/374,247

(22) Filed: Dec. 9, 2016

(30) Foreign Application Priority Data
Mar. 23, 2016 (JP) 2016-058856

(51) Int. Cl. H01L 51/52; H01L 27/32; H01L 51/56

(52) U.S. Cl. CPC H01L 51/5253; H01L 51/56; H01L 27/3244; H01L 2227/323

(57) ABSTRACT

A method of manufacturing an organic EL display device according to an embodiment of the present invention includes, in the following order, disposing a mask material so as to specify a region having a sealing layer formed therein, on a substrate in which a laminated structure having a first electrode, an organic EL layer, and a second electrode included in this order is disposed, applying a sealing layer forming material onto the substrate, and removing the mask material from an upper portion of the substrate.

### CROSS-REFERENCE TO RELATED APPLICATION

The present application claims priority from the Japanese Application JP2016-058856 filed on Mar. 23, 2016. The Japanese Application JP2016-058856 is incorporated by reference into this application.

### BACKGROUND OF THE INVENTION

1. Field of the Invention

One or more embodiments of the present invention relates to a method of manufacturing an organic EL display device.

2. Description of the Related Art

For example, as disclosed in JP 2015-176717 A, in an organic EL element structure, a method of sealing a laminated structure in which a first electrode, an organic EL layer and a second electrode are included in this order is adopted in order to protect an organic EL layer from moisture or the like.

### SUMMARY OF THE INVENTION

An example of the sealing method to be used includes a method of combining an inorganic material film with an organic material layer, from the viewpoint of coatability of foreign substances which are present on an organic EL element structure. However, the coating of foreign substances may be not sufficient in the end of a sealing region. In a case where the coating of foreign substances is not sufficient, there is a concern of, for example, the infiltration of moisture to an organic EL layer being caused.

One or more embodiments of the present invention is contrived in view of such circumstances, and an object thereof is to realize a method of manufacturing an organic EL display device which is excellent in the coatability of foreign substances in the end of a sealing region.

According to one aspect of the present invention, a method of manufacturing an organic EL display device is provided. The method includes, in the following order, disposing a mask material so as to specify a region having a sealing layer formed therein, on a substrate in which a laminated structure having a first electrode, an organic EL layer, and a second electrode included in this order is disposed, applying a sealing layer forming material onto the substrate, and removing the mask material from an upper portion of the substrate.

In one embodiment of the present invention, an end surface of the sealing layer to be formed includes a taper region.

In one embodiment of the present invention, the sealing layer forming material includes a curable resin composition, and the method includes removing the mask material, and then curing the sealing layer forming material.

In one embodiment of the present invention, the sealing layer forming material is applied using an ink jet method.

In one embodiment of the present invention, the method includes applying the sealing layer forming material to form a sealing layer, and then forming an inorganic sealing film on the sealing layer.

### BRIEF DESCRIPTION OF THE DRAWINGS

FIG. 1 is a diagram illustrating an outline of a circuit configuration of an organic EL display device.

FIG. 2 is a diagram illustrating an example of a circuit diagram of the organic EL display device.

FIG. 3A is a diagram illustrating an example of a portion of a cross-section of the organic EL element structure.

FIG. 3B is a diagram illustrating an outline of across-section of a TFT layer included in the organic EL element structure shown in FIG. 3A.

FIG. 4A is a diagram illustrating a method of manufacturing an organic EL display device in one embodiment of the present invention.

FIG. 4B is a diagram illustrating a method of manufacturing an organic EL display device in one embodiment of the present invention.

FIG. 4C is a diagram illustrating a method of manufacturing an organic EL display device in one embodiment of the present invention.

FIG. 4D is a diagram illustrating a method of manufacturing an organic EL display device in one embodiment of the present invention.

FIG. 4E is a diagram illustrating a method of manufacturing an organic EL display device in one embodiment of the present invention.

### DETAILED DESCRIPTION OF THE INVENTION

Hereinafter, each embodiment of the present invention will be described with reference the accompanying drawings. The disclosure is merely illustrative, and appropriate changes without departing from the spirit of the invention which can be readily conceived by those skilled in the art are naturally contained in the scope of the present invention. In addition, in order to make the description clearer, the drawings may be schematically shown for the width, thickness, shape and the like of each unit as compared to the embodiment, but are merely illustrative, and are not intended to limit the interpretation of the present invention. In addition, in the present specification and each drawing, the same components as those described in the previous drawings are denoted by the same reference numerals and signs, and thus the detailed description thereof may not be given.

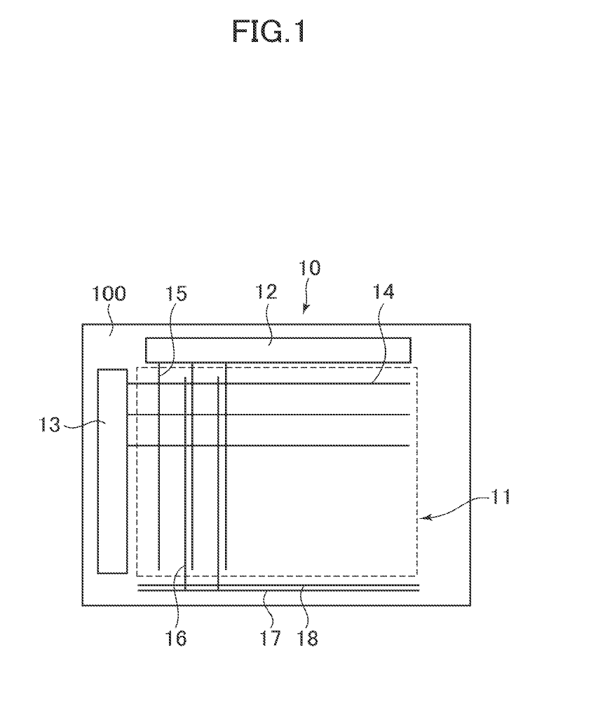

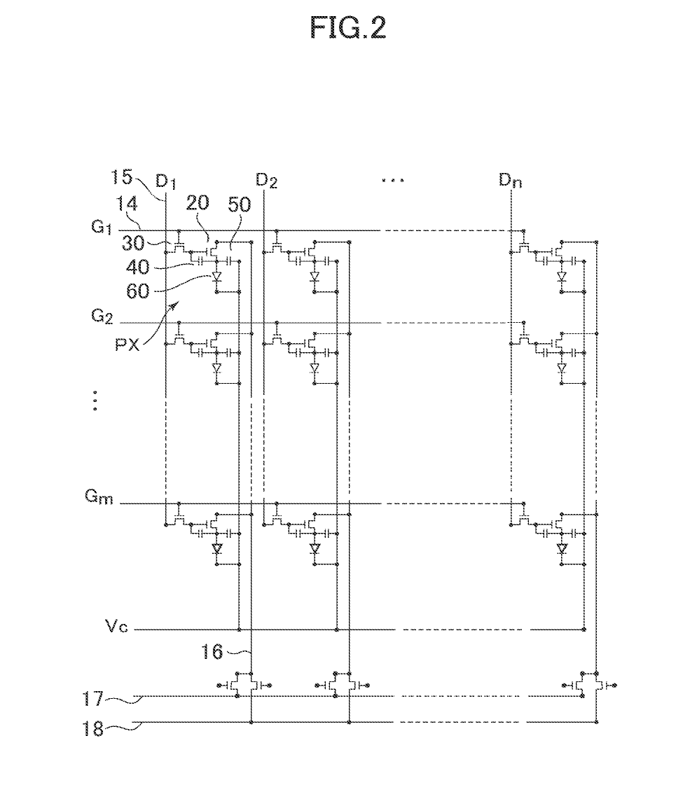

FIG. 1 is a schematic diagram illustrating a circuit configuration of an organic EL display device, and FIG. 2 shows an example of a circuit diagram of the organic EL display device.

An organic EL display device 10 controls each pixel formed in a display region 11 on a substrate 100 by a data drive circuit 12 and a scanning drive circuit 13 and displays an image. Here, for example, the data drive circuit 12 is an integrated circuit (IC) that generates and transmits a data signal to be sent to each pixel, and the scanning drive circuit 13 is an IC that generates and transmits a gate signal to a thin film transistor (TFT) included in a pixel. In FIG. 2, the data drive circuit 12 and the scanning drive circuit 13 are respectively shown to be formed in two places, but may be incorporated into one IC, and may be formed by a circuit which is wired directly on the substrate 100.

A scanning line 14 for transmitting a signal from the scanning drive circuit 13 is connected to the gate electrode of a switching transistor 30 as shown in FIG. 1. In addition, a data line 15 for transmitting a signal from the data drive circuit 12 is connected to the source and drain electrode of the switching transistor 30. A reference potential for causing an organic light-emitting diode 60 to emit light is applied to a potential wiring 16 which is connected to the source and drain electrode of a driver transistor 20. A first potential supply wiring 17 and a second potential supply wiring 18 are connected to a potential supply source, and are connected to the potential wiring 16 through transistors. The configuration shown in FIG. 1 is an example, and the present embodiment is not limited thereto.

As shown in FIG. 2, in the display region 11 of the organic EL display device 10, n (D1 to Dn) data lines 15 are formed, and m (G1 to Gm) scanning lines 14 are formed. A plurality of pixels PX are arranged in a matrix in the extending direction of the scanning line 14 and the extending direction of the data line 15. For example, the pixels PX are formed in portion surrounded by G1 and G2, and D1 and D2.

The first scanning line G1 is connected to the gate electrode of the switching transistor 30, and the switching transistor 30 is set to be in an on-state when a signal is applied from the scanning drive circuit 13. Consequently, when a signal is applied from the data drive circuit 12 to the first data line D1, electric charge is stored in a storage capacitor 40, a voltage is applied to the gate electrode of the driver transistor 20, and the driver transistor 20 is set to be in an on-state. Here, even when the switching transistor 30 is set to be in an off-state, the driver transistor 20 is set to be in an on-state for a certain period of time due to the electric charge stored in the storage capacitor 40. Since the anode of the organic light-emitting diode 60 is connected to the potential wiring 16 through between the source and drain of the driver transistor 20, and the cathode of the organic light-emitting diode 60 is fixed to a reference potential Vc, a current flows to the organic light-emitting diode 60 in accordance with the gate voltage of the driver transistor 20, and the organic light-emitting diode 60 emits light. In addition, an additional capacitor 50 is formed between the anode and the cathode of the organic light-emitting diode 60. The additional capacitor 50 exhibits an effect of stabilizing a voltage to be written in the storage capacitor 40, and contributes to the stable operation of the organic light-emitting diode 60. Specifically, the effect is exhibited by the capacitance of the additional capacitor 50 becoming larger than the capacitance of the storage capacitor 40.

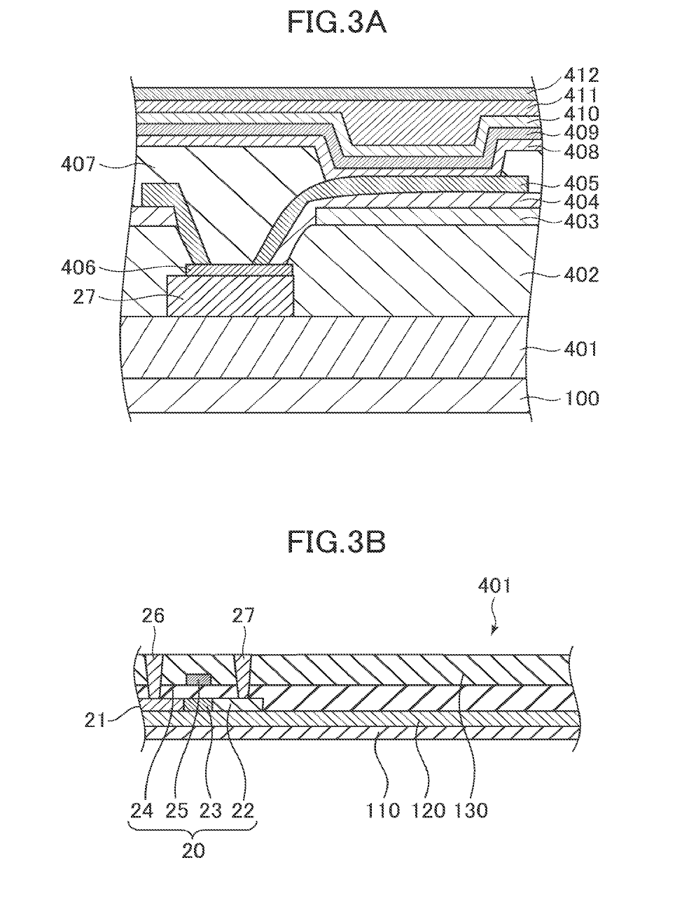

FIG. 3A is a diagram illustrating an example of a portion of a cross-section of the organic EL element structure, and FIG. 3B is a diagram schematically illustrating an outline of a cross-section of a TFT layer 401 shown in FIG. 3A.

As shown in FIG. 3A, the TFT layer 401 having a TFT and the like for driving a pixel formed therein is provided on the substrate 100. As shown in FIGS. 3A and 3B, for example, a first underlying film 110 constituted of SiNₓ or the like and a second underlying film 120 constituted of SiOₓ or the like are formed on the substrate 100 in this order. A drain electrode layer 21, a source electrode layer 22, and a channel layer 23 are formed on the second underlying film 120. A gate insulating film 24 is formed so as to cover the drain electrode layer 21, the source electrode layer 22, the channel layer 23 and the second underlying film 120, and then a gate electrode layer 25 is formed above the channel layer 23. An interlayer insulating film 130 is formed so as to cover the gate electrode layer 25 and the gate insulating film 24, and through-holes reaching the drain electrode layer 21 and the source electrode layer 22, respectively, are formed. A drain electrode 26 and a source electrode 27 are formed in the respective through-holes.

As shown in FIG. 3A, a planarization layer 402 is formed so as to cover the drain electrode 26, the source electrode 27 and the interlayer insulating film 130. A metal layer 403, an insulating layer 404, and an anode electrode 405 are formed on the planarization layer 402 in this order. The metal layer 403 includes, for example, an Al layer, and reflects light from a light-emitting layer on the surface of the metal layer 403.

The metal layer 403 and a cathode electrode 409 described later are electrically connected to each other, and thus the metal layer 403 is used as an auxiliary wiring of the power supply wiring of the cathode electrode 409. In addition, a capacitor layer (additional capacitor 50) is formed by the metal layer 403 and the anode electrode 405 with the insulating layer 404 interposed therebetween. Electrical connection between the metal layer 403 and the cathode electrode 409 is performed, for example, by providing a through-hole outside of a display region. The insulating layer 404 is formed of, for example, SiNₓ. The anode electrode 405 can be formed of any appropriate material. For example, an Al-based material, or a transparent conductive material such as an indium tin oxide (ITO) or an indium zinc oxide (IZO) is used.

In addition, as shown in FIG. 3A, a through-hole on the source electrode 27 is formed in the planarization layer 402. An ITO layer 406 is formed on the bottom of this through-hole, and the insulating layer 404 and the anode electrode 405 are laminated on the lateral side of the through-hole facing a light-emitting region. In addition, the anode electrode 405 is laminated on the opposite lateral side of the through-hole.

In addition, an RIB layer 407 for separating a pixel is formed on the above structure, and an organic EL layer 408 is formed on the RIB layer 407 and the anode electrode 405. Here, a region in which the anode electrode 405 and the organic EL layer 408 are in contact with each other serves as a light-emitting region, and the RIB layer 407 specifies the outer edge of the light-emitting region.

The cathode electrode 409 is formed on the organic EL layer 408. The cathode electrode 409 is formed of, for example, a transparent conductive material such as an ITO or an IZO. The cathode electrode 409 may be formed across some of the pixels PX, or all of the pixels PX arranged in a matrix. The organic EL layer 408 is formed by, for example, laminating a hole transport layer, a light-emitting layer, and an electron transport layer in order from the anode electrode 405 side, but is well-known, and thus the detailed description thereof will not be given.

A first sealing film 410 is provided on the cathode electrode 409, and a second sealing film 412 is provided on the first sealing film 410 through the intermediation of a sealing layer (planarization layer) 411 including an organic material interposed therebetween.

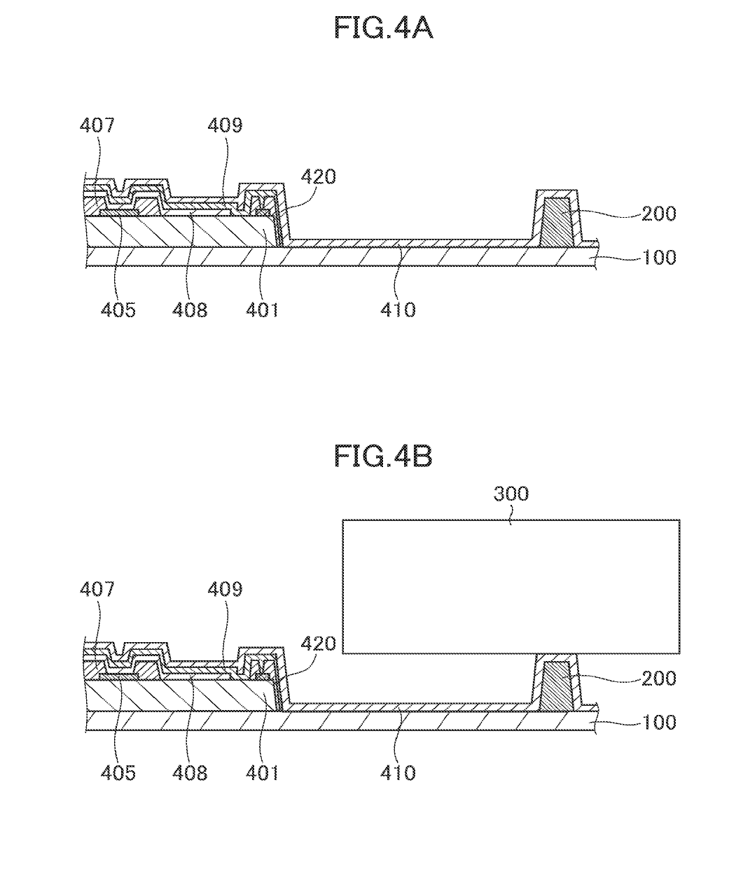

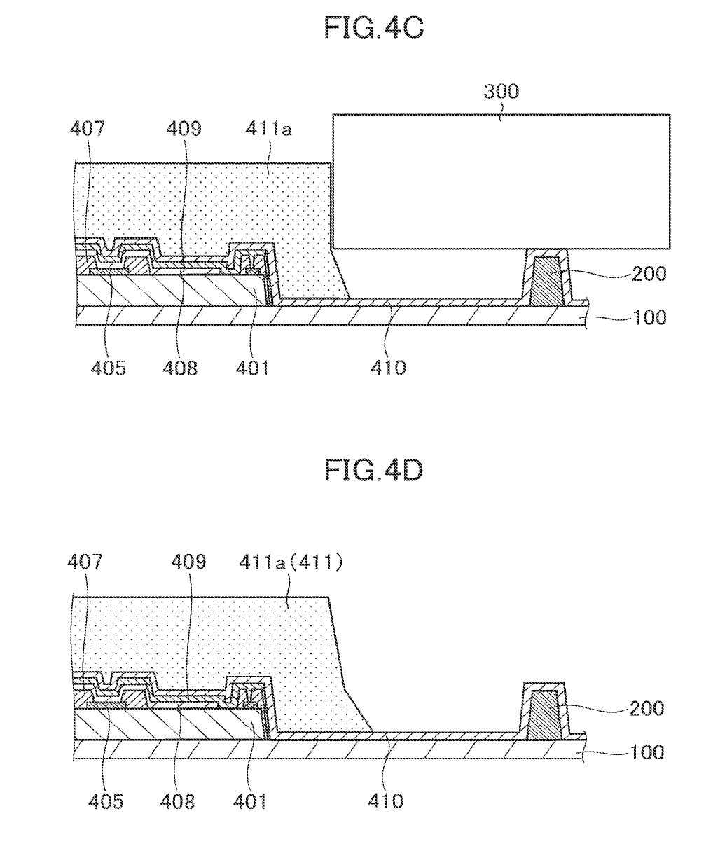

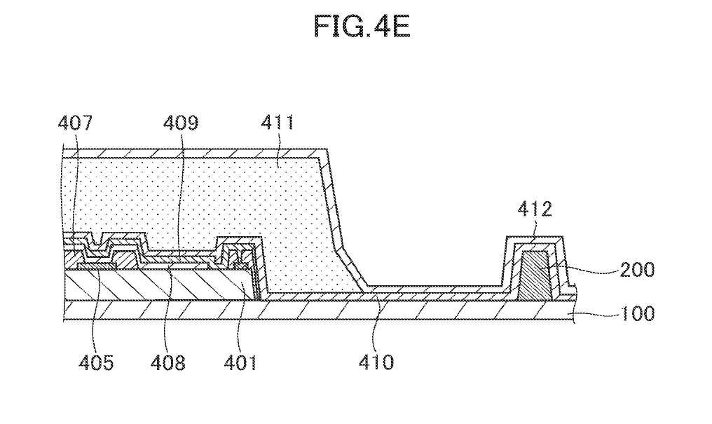

Hereinafter, a method of manufacturing an organic EL display device in one embodiment of the present invention will be described with reference to FIGS. 4A to 4E. Here, a method of manufacturing a general organic EL display device itself is well-known, and thus the description thereof will not be given. In the following, a method of forming a sealing layer in the method of manufacturing an organic EL display device of the present embodiment will be mainly described. FIGS. 4A to 4E show only the substrate 100, the TFT layer 401, the first electrode 405, the RIB layer 407, the organic EL layer 408, the second electrode 409, the first sealing film 410, the sealing layer (planarization layer) 411 and the second sealing film 412.

As shown in FIG. 4A, the first sealing film 410 (for example, inorganic film such as SiNₓ) is formed on a laminated structure which is disposed on the TFT layer 401 provided on the substrate 100, and in which the first electrode 405, the organic EL layer 408, and the second electrode 409 are included in this order. The first sealing film 410 prevents moisture from infiltrating into the organic EL layer 408, and thus is formed so as to cover even an organic EL element structure end 420.

In the shown example, a dam 200 surrounding a display region is formed on the substrate 100. The first sealing film 410 is formed so as to cover even the dam 200 continuously from the organic EL element structure end 420. The dam 200 is formed of, for example, a resin material in a line shape so as to have a predetermined width and height.

Next, as shown in FIG. 4B, a mask material (for example, metal plate) 300 is disposed on the substrate 100 so as to specify a region having a sealing layer formed therein. Specifically, the mask material 300 is disposed at a predetermined interval (for example, approximately 20 μm) outward from the organic EL element structure end 420. In the shown example, the mask material 300 is disposed on the dam 200. As long as the mask material 300 can prevent a sealing layer forming material from being applied to portions other than a desired area, there is no particular limitation to its shape, thickness and the like.

Next, as shown in FIG. 4C, a sealing layer forming material is applied so that a sealing layer having a predetermined thickness (for example, approximately 10 μm) is obtained, and a coating film 411a is formed. Since the mask material 300 is disposed outside of the organic EL element structure end 420, it is possible to suppress the spread of the applied sealing layer forming material (coating film 411a) to the outside.

The sealing layer forming material typically includes a curable resin composition. As a method of applying the sealing layer forming material, any appropriate method can be adopted. For example, an ink jet method is used. In a case where the ink jet method is adopted, the viscosity of the sealing layer forming material is set to be low, for example, in order to stably eject the material from nozzles.

Thereafter, as shown in FIG. 4D, the mask material 300 is removed from the upper portion of the substrate 100. The mask material 300 is removed, for example, before the curing of the applied sealing layer forming material (coating film 411a) is completed. Specifically, after the mask material 300 is removed, the end of the coating film 411a of which the curing is not completed spreads to the outside, and thus a taper region can be formed on the end surface of the coating film 411a, as shown in FIG. 4D. In this state, the coating film 411a is cured by, for example, UV irradiation, heating or the like. The taper angle (angle of contact with respect to the surface of a substrate) of the taper region included in the end surface of the sealing layer 411 obtained in this manner is preferably equal to or greater than 30° and equal to or less than 90°. As described above, the sealing layer is formed using the mask material 300, and thus it is possible to achieve such a high taper angle. As a result, it is possible to secure the thickness of the end of a sealing region, and to satisfactorily coat foreign substances which are present in the vicinity of the organic EL element structure end 420. Furthermore, it is possible to achieve a high yield rate. In a case where a sealing layer forming material having low viscosity is applied without using a mask material, the taper angle is set to be, for example, approximately 2° to 3°. Thereby, foreign substances which are present in the vicinity of the organic EL element structure end are not sufficiently coated, and a yield rate also deteriorates.

Next, as shown in FIG. 4E, the second sealing film 412 is formed on the sealing layer 411 (for example, an inorganic film such as SiNₓ is formed by a CVD method or the like). As described above, with the formation of the taper region on the end surface, the surface of the sealing layer 411 is satisfactorily coated with the second sealing film 412 (there is no area in which the second sealing film 412 is broken, and the sealing layer 411 is exposed), and thus it is possible to effectively prevent moisture from infiltrating into the organic EL layer 408.

The present invention can be variously modified without being limited to the aforementioned embodiment. For example, it is possible to make a replacement with a configuration capable of achieving substantially the same configuration as the configuration shown in the embodiment, a configuration exhibiting the same operational effect or the same object.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A method of manufacturing an organic EL display device, the method comprising, in the following order:
disposing a mask material so as to specify a region having a sealing layer formed therein, on a substrate in which a laminated structure having a first electrode, an organic EL layer, and a second electrode included in this order is disposed;
applying a sealing layer forming material onto the substrate; and
removing the mask material from an upper portion of the substrate.

2. The manufacturing method according to claim 1, wherein an end surface of the sealing layer to be formed includes a taper region.

3. The manufacturing method according to claim 1, wherein the sealing layer forming material includes a curable resin composition, and the method comprises removing the mask material, and then curing the sealing layer forming material.

4. The manufacturing method according to claim 1, wherein the sealing layer forming material is applied using an ink jet method.

5. The manufacturing method according to claim 1, comprising applying the sealing layer forming material to form a sealing layer, and then forming an inorganic sealing film on the sealing layer.
